(19) United States
(12) Patent Application Publication
(10) Pub. No.: US 2005/0275030 A1
(43) Pub. Date: Dec. 15, 2005

(54) Semiconductor device and method of manufacturing the same

(75) Inventor: Hirokazu Hayashi, Minato-ku (JP)

Correspondence Address: SHINJYU GLOBAL IP COUNSELORS, LLP, 1233 20TH STREET, NW, SUITE 700, WASHINGTON, DC, 20036-2680, US

(73) Assignee: Oki Electric Co., Ltd., Minato-ku (JP)

(21) Appl. No.: 10/989,011

(22) Filed: Nov. 16, 2004

(30) Foreign Application Priority Data
Jun. 14, 2004 (JP) 2004-175403

(51) Int. Cl. H01L 21/336

(52) U.S. Cl. 257/355

(57) ABSTRACT

The present invention provides a method of manufacturing an ESD protection device with a gate electrode structure that reduces surge voltage applied to a gate insulating film and inhibits destruction of the gate insulating film. A method of manufacturing a semiconductor device includes steps of preparing a support substrate, forming a device region and a device-separation region on the support substrate, forming a gate insulating film in the device region, forming a first gate electrode on the gate insulating film, implanting a first impurity ion into the first gate electrode, and decreasing a first impurity ion concentration by implanting a second impurity ion with a polar character, which is opposite from that of the first impurity ion, into the first gate electrode.

### BACKGROUND OF THE INVENTION

Field of the Invention

The present invention relates to a semiconductor device and a method of manufacturing the same. More specifically, the present invention relates to a semiconductor device that protects an internal circuit from electrostatic damage and the manufacture thereof.

For a semiconductor device, especially for an integrated circuit with a metal-oxide semiconductor (MOS) transistor, an important task is how the device could be protected from electrostatic discharge (ESD) that is generated from human bodies or other devices. Related examples of a transistor protection device that deals with ESD are described in Japanese Patent Publications JP-A-54-127684, JP-A-62-193164, and JP-A-2003-007833, which are hereby incorporated by reference.

Japanese Patent Publication JP-A-54-127684 discloses a transistor protection device, which reduces the influence of surge voltage applied to an internal circuit from an external input terminal by using a combination of resistance by a diffusion layer and the junction capacitance. The diffusion layer has an opposite conductivity from a support substrate. The junction capacitance is generated in a place between the diffusion layer and the support substrate. The transistor protection device enhances a level of withstand pressure by increasing junction capacitance.

Japanese Patent Publication JP-A-62-193164 discloses a transistor protection device, which reduces an influence of surge voltage by using a combination of a resistance layer of polysilicon, capacitance by a silicon dioxide film formed on a surface of a support substrate, and capacitance by a PN junction formed inside the support substrate. The protection device enhances a level of withstand pressure with a partial pressure effect by a series connection of silicon dioxide film capacitance and junction capacitance.

Japanese Patent Publication JP-A-2003-007833 discloses an MOS transistor type protection device, which has a control gate and a floating gate. The control gate is connected to an input/output wiring, and the floating gate is connected to an electrode wiring through a resistance. When surge voltage is applied to an input/output terminal, the electric potential of a floating gate rises through the control gate, and a transistor firstly operates in a pinch-off action. This action works as a trigger for a parasitic bipolar to function, and snapback breakdown is equally generated throughout the transistor and discharge is generated. Due to this structure, junction destruction in a local area of the transistor is inhibited and the withstand pressure for electrostatic destruction is enhanced. Furthermore, the incidence rate of a gate insulating film destruction can be reduced, because breakdown voltage is set down.

Japanese Patent Publication JP-A-2003-007833 also discloses a transistor protection device in accordance with another embodiment, which has a gate electrode structure in which capacitance of an insulating film formed in the place between a control gate electrode and a floating gate electrode, depletion layer capacitance of a floating gate electrode, and capacitance of a tunneling oxide film are series-connected. Depletion layer capacitance of a floating gate electrode depends on surge voltage, and therefore the protection function takes advantage of this to function effectively only for larger surge voltages.

In a nonpatent literature, Chatterjee et al. discloses a protection device that combines an MOS transistor and a silicon controlled rectifier (SCR) (“A Low-Voltage Triggering SCR for On-Chip ESD Protection at Output and Input Pads,” IEEE ELECTRON DEVICE LETTERS. Vol. 12. No. 1. January 1991, which is hereby incorporated by reference). With the high-integration of semiconductor devices in recent years, operating voltage of an internal circuit can be lowered. When ESD protection is conducted, trigger voltage of a protection device must be lower than the voltage that can cause damage to a semiconductor device. An SCR is one of the effective ESD protection devices, but it has a problem in that its trigger voltage is high. Therefore, an MOS transistor with low operating voltage is combined in the protection device as a low voltage trigger element.

With the miniaturization of a semiconductor device, area of a device in a transistor protection device is also required to be small. In addition, in order to improve the performance of a semiconductor device, it is preferable that junction capacitance and protection resistance of a protection device to be load is small.

In the protection devices described in Japanese Patent Publications JP-A-54-127684 and JP-A-62-193164, a method of reducing influence of surge voltage by using a combination of protection resistance and junction capacitance is used. In these cases, when a higher surge voltage to be applied, a higher protection resistance and junction capacitance are required. Therefore, the area of a device consequently becomes large to meet the withstand pressure that is demanded.

The protection device described in Japanese Patent Publication JP-A-2003-007833 uses the snapback phenomenon of an MOS transistor. Due to this structure, voltage clamp functioning of the protection device is better than that of the protection device using normal resistance and junction capacitance. However, in general, an MOS transistor type protection device has a risk that electrostatic destruction is generated in a gate oxide film when surge voltage beyond the limit of acceptance is applied to the gate oxide film. In the patent publication, there is no description of a method to inhibit directly electrostatic destruction in the gate oxide film of the protection device. Further, a gate electrode in the protection device has a stacked gate structure that is generally used for nonvolatile memory. In other words, a structure in which a floating gate electrode is implanted in a gate oxide film and a control gate electrode are laminated. Therefore, an MOS transistor type protection device with a general gate electrode structure requires a method of assembly and a structure that easily inhibits electrostatic destruction in a gate oxide film.

In view of the above, it will be apparent to those skilled in the art from this disclosure that there exists a need for an improved semiconductor device and a method of manufacturing the same. This invention addresses this need in the art as well as other needs, which will become apparent to those skilled in the art from this disclosure.

### SUMMARY OF THE INVENTION

It is an object of the present invention to provide an MOS transistor type protection device with a gate electrode structure that easily inhibits electrostatic destruction in a gate oxide film and a method of making the same.

A manufacturing method of a transistor protection device in accordance with a first aspect of the present invention includes steps of preparing a support substrate, forming a device region and a device-separation region on the support substrate, forming a gate insulation film on the device region, forming a first gate electrode on a gate insulating film, implanting a first impurity ion into the first gate electrode, and reducing a first impurity ion concentration partially by implanting a second impurity ion with a polarity character, which is opposite from that of the first impurity ion, into the first gate electrode.

Further, a manufacturing method of a transistor protection device in accordance with a second aspect of the present invention is the method of the first aspect and further includes steps of forming an insulation film on the first gate electrode and forming a second gate electrode on the insulation film after implantation of the second gate electrode on the insulating film.

According to the present invention, an impurity ion concentration of a gate electrode is partially reduced. For example, a low impurity ion concentration layer is formed on or adjacent to a surface of a gate electrode, and high value is set on the resistance of the part. The incidence rate of electrostatic destruction of a gate insulating film is reduced by partially reducing surge voltage that is externally applied, and inhibiting high surge voltage that is directly applied to a gate oxide film.

These and other objects, features, aspects, and advantages of the present invention will become apparent to those skilled in the art from the following detailed description, which, taken in conjunction with the annexed drawings, discloses a embodiment of the present invention.

### BRIEF DESCRIPTION OF THE DRAWINGS

Referring now to the attached drawings which form a part of this original disclosure:

FIG. 1(a) is a view of construction drawing of a gate electrode in an MOS transistor in accordance with a first embodiment of the present invention;

FIG. 1 is a view of a circuit diagram of an equivalent circuit of the gate electrode of FIG. 1(a);

FIG. 2(a) is a view of construction drawing of a gate electrode in an MOS transistor in accordance with a second embodiment of the present invention;

FIG. 2(b) is a view of a circuit diagram of an equivalent circuit of the gate electrode of FIG. 2(a);

FIG. 3 is a view of cross-section diagrams illustrating the process of a manufacturing method of an MOS transistor in accordance with the first and second embodiments of the present invention;

FIG. 4 is a view of cross-section diagrams illustrating the process of a manufacturing method of an MOS transistor in accordance with the second embodiment of the present invention; and

FIG. 5 is a circuit diagram of an example of a protection device using an MOS transistor in accordance with the second embodiment of the present invention.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

In an MOS transistor type protection device in accordance with a first preferred embodiment of the present invention, influence of surge voltage that is applied to a gate oxide film is reduced by forming a high resistance region, which is made of a low impurity ion concentration layer, adjacent to a surface of a gate electrode.

The Gate Electrode Structure

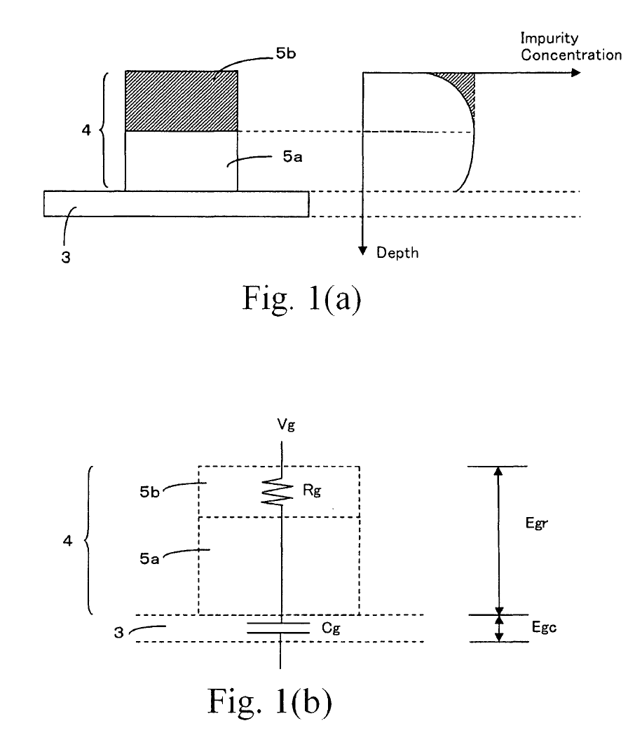

FIG. 1(a) is a diagram illustrating a structure of a gate electrode and impurity profile in an MOS transistor type protection device in accordance with the first embodiment of the present invention. A gate electrode 4 has a high impurity ion concentration layer 5a and a low impurity ion concentration layer 5b. The low impurity ion concentration layer 5b is formed on or adjacent to a surface of the gate electrode 4 to increase resistance of an upper layer of the gate electrode 4. Here, it could be assumed that the low impurity ion concentration layer 5b is formed on the side of a gate oxide film (gate insulating film) 3. However, in this case, a depletion layer in the gate electrode 4, which is generated when surge voltage is applied, spreads on the side of the gate oxide film 3. This is equivalent to the gate oxide film 3 effectively thickening, and resulting in the degradation of driving capacity of a transistor. Therefore, it is preferable that the low impurity ion concentration layer 5b be formed on or adjacent to the surface of the gate electrode 4.

FIG. 1(b) is a diagram illustrating an equivalent circuit in the structure of the gate electrode. When resistance of the low impurity ion concentration layer 5b is set as Rg, and capacity of the gate oxide film 3 is set as Cg, the equivalent circuit could be thought as a series circuit of RC. Further, the high impurity ion concentration layer 5a, which is the lower layer of the gate electrode 4, is a conductor, and its resistance component is set to zero.

Now, it is assumed that a pulse of surge voltage Vg is applied in the equivalent circuit described in FIG. 1(b). When voltage applied to Rg and Cg are set as Egr and Egc respectively, they can be expressed as a function of time (t) by the following equations (1) and (2).
Egr=Vg×exp(−t/(Rg×Cg) (1)
Egc=Vg×(1−exp(−t/(Rg×Cg) (2)

In reference to the equations (1) and (2), it can be seen that at the moment when surge voltage Vg is applied, that is, when the t is nearly equal to zero, the following equations are derived: Egr=Vg, and Egc=0. That is, all the surge voltage Vg is only applied to a resistance component Rg.

In addition, when a given amount of time passes after the surge voltage is applied, Egc is determined by the equation (2) that includes a time constant determined by the resistance component Rg and the capacity component Cg.

A Manufacturing Process

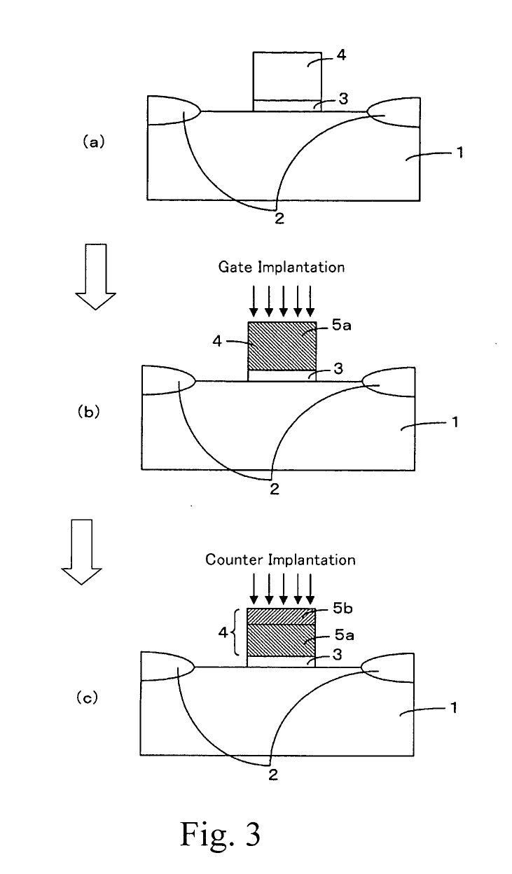

FIG. 3 shows cross-section diagrams illustrating a method of manufacturing an MOS transistor in accordance with the first embodiment of the present invention.

First, as is shown in line (a) of FIG. 3, a silicon dioxide film and a silicon nitride film that work as a buffer are formed on a silicon support substrate 1 in order, and a field oxide film 2 is formed using a method such as a normal method of Local Oxidation of Silicon (LOCOS), and accordingly device separation is conducted. Thus, the field oxide film 2 is part of the device-separation region with an area where the field oxide film 2 does not extend being the device region. A substrate used for the silicon support substrate 1 is not restricted to a bulk substrate, and a silicon on insulator (SOI) substrate can be used. Then, the gate oxide film 3 is formed on the silicon support substrate 1. Thickness of the gate oxide film 3 is determined by electrostatic withstand pressure that is required in a protection device. For instance, when electrostatic withstand pressure is 3.5 V, thickness of the gate oxide film 3 is 70 angstroms. Further, when electrostatic withstand pressure is 1 V, thickness of the gate oxide film 3 is 20 angstroms. Then, polysilicon film is deposited on the gate oxide film 3, and the gate electrode 4 is formed by lithography and etching.

Next, as is shown in line (b) of FIG. 3, impurity ions are implanted into the gate electrode 4 to reduce sheet resistance, and a high impurity ion concentration layer 5a is formed. In general, a group V element, such as phosphorus (P) or arsenic (As), is used for NMOS as the ion species, and a group III element, such as boron (B), is used for PMOS as the counter ion species.

Then, as is shown in line (c) of FIG. 3, counter ion implantation is conducted into the gate electrode 4. This is a low impurity ion concentration layer 5b that is formed adjacent to or on the surface of the gate electrode 4 by implanting impurity ions into the gate electrode 4. The impurity ions have an opposite polarity from that of the described impurity ion species to reduce sheet resistance. In general, a group III element, such as B, is used for NMOS as the counter species, and a group V element, such as P or As, is used for PMOS as the ion species.

Subsequently, an MOS transistor is formed with a heretofore known method (not shown in the diagrams).

An Example of a Protection Device

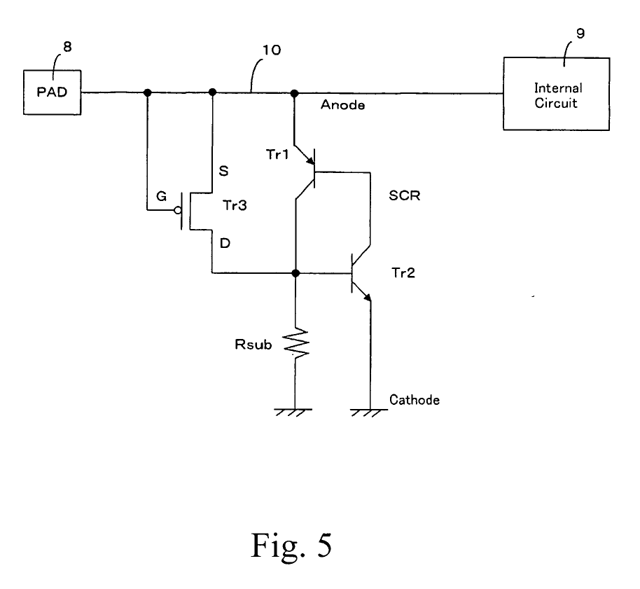

FIG. 5 is an example of an ESD protection circuit using an MOS transistor that has the gate electrode structure of the present invention. The circuit is similar to a protection circuit that combines an SCR and an MOS transistor. As mentioned, Chatterjee et al. also describe a protection circuit that combines an SCR and MOS transistor. Differences between the two will be apparent in the following description.

The protection circuit is connected to a line 10 that connects an input/output terminal 8 and an internal circuit 9. The protection circuit has an SCR that an anode connects to the line 10. The protection circuit also has a cathode and a GND that are connected. The SCR is made of a PNP transistor Tr1 and an NPN transistor Tr2. Further, a base of the PNP transistor Tr1 and a corrector of the NPN transistor Tr2 are connected, and a corrector of the PNP transistor Tr1 and a base of the NPN transistor Tr2 are connected. The described anode corresponds to an emitter of the PNP transistor Tr1, and the described cathode corresponds to an emitter of the NPN transistor Tr2. In addition, substrate resistance Rsub is located in the place between a base of NPN transistor Tr2 and GND.

Furthermore, a PMOS transistor Tr3, which is a low voltage trigger device, is connected in a place between the line 10 and the base of the NPN transistor Tr2. A gate and a source of Tr3 are connected to the line 10, and a drain of the Tr3 is connected to the base of the NPN transistor Tr2. The PMOS transistor Tr3 has a gate electrode structure in accordance with the first embodiment of the present invention.

Now, it is assumed that a surge voltage with a straight polarity is applied to the input/output terminal 8. The surge voltage is applied to the gate and the source of the PMOS transistor Tr3 and the anode of an SCR (an emitter of the PNP transistor Tr1), and voltage drop is caused in a part of the high resistance region adjacent to the surface of the gate electrode in the gate of the PMOS transistor Tr3. Due to the voltage drop, the surge voltage that is actually applied to a gate oxide film becomes smaller than the surge voltage that is applied to the source. When the potential difference between the gate and the source increases more than threshold voltage of the PMOS transistor Tr3, the PMOS transistor Tr3 turns on. This triggers the SCR to be turned on, and then the SCR discharges the surge voltage to a GND. Due to this structure, the internal circuit 9 is protected from surge voltage.

In an example of the protection circuit, the protection device with a PMOS transistor is explained, but if a circuit has the structure in which surge voltage is directly applied to the gate of the protection device, the present invention works for both the PMOS and the NMOS regardless of difference between them.

Operation/Working-Effect

In general, as seen in FIG. 3, the thickness of the gate oxide film 2 in an MOS transistor type protection device has to be thickly formed to ensure electrostatic withstand pressure against large surge voltages. According to a transistor protection device in accordance with the first embodiment of the present invention, forming a high resistance region that is made of a low impurity ion concentration layer 5b on a place on or adjacent to the surface of the gate electrode 4, and reducing surge voltage partially in the high resistance region, can inhibit the high surge voltage that is directly applied to the gate oxide film 4. Given this structure, even a gate oxide film whose thickness is as thin as that of an MOS transistor used for an internal circuit can be provided with adequate ESD protection performance and can reduce the incidence rate of a gate oxide film disruption. In addition, a manufacturing process of the first embodiment of the present invention is convenient, because the manufacturing process is formed by adding a step of the counter ion implantation into the gate electrode to a heretofore example.

As used herein, the following directional terms “forward, rearward, above, downward, vertical, horizontal, below and transverse” as well as any other similar directional terms refer to those directions of a device equipped with the present invention. Accordingly, these terms, as utilized to describe the present invention should be interpreted relative to a device equipped with the present invention.

### Second Embodiment

A second embodiment will now be explained. In view of the similarity between the first and second embodiments, the parts of the second embodiment that are identical to the parts of the first embodiment will be given the same reference numerals as the parts of the first embodiment. Moreover, the descriptions of the parts of the second embodiment that are identical to the parts of the first embodiment may be omitted for the sake of brevity.

The second embodiment of the present invention is an alternate version of the first embodiment of the present invention. In the second embodiment, an oxide film is further formed on a high resistance region of the gate electrode and a capacity component is added. Due to this structure, influence of surge voltage that is applied to the gate oxide film is reduced.

The Gate Electrode Structure

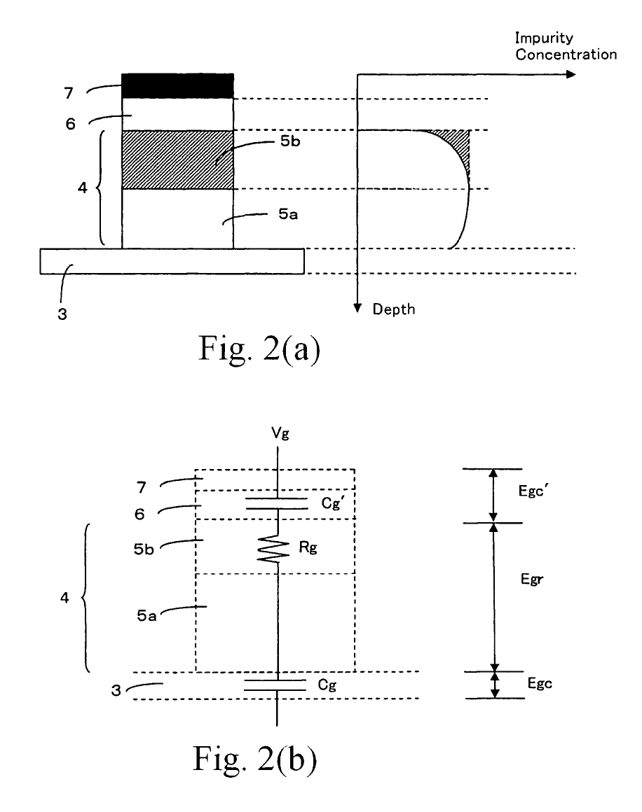

FIG. 2(a) illustrates a gate electrode structure and impurity profile of an MOS transistor type protection device in accordance with the second embodiment of the present invention. A low impurity ion concentration layer 5b is formed on an upper layer of a gate electrode 4 as a resistance component. A silicon dioxide film 6 is formed on the gate electrode 4 as a capacity component, and an electrode 7, which is made of metal or silicide, is formed on the silicon dioxide film 6.

FIG. 2(b) is an equivalent circuit in the gate electrode structure. When resistance of the low impurity ion concentration layer 5b is defined as Rg, capacity of the silicon dioxide film 6 is defined as Cg′, and capacity of a gate oxide film 3 is defined as Cg, it can be assumed that the equivalent circuit is a series circuit of RC. In addition, a high impurity ion concentration layer 5a in a lower layer of the gate electrode 4 and the electrode 7 in the uppermost part of the gate electrode 4 are defined as conductors, and their resistance components are set to zero.

Now, it is assumed that a pulse of surge voltage Vg is applied in the equivalent circuit described in FIG. 2(b). When voltage applied to Rg, Cg′, and Cg are defined as Egr, Egc′, and Egc respectively, they can be expressed as functions of time (t) by the following equations (3) through (5).
Egr=Vg×exp(−t×(Cg′+Cg)/Rg/Cg′/Cg) (3)
Egc′=Vg×Cg(Cg′+Cg)×(1−exp(−t×(Cg′+Cg)/Rg/Cg′/Cg)) (4)
Egc=Vg×Cg′/(Cg′+Cg)×(1−exp(−t×(Cg′+Cg)/Rg/Cg′/Cg)) (5)

In reference to the equations (3) through (5), it is obvious that at the moment when the surge voltage Vg is applied, that is, when t nearly equals zero, the following equations are derived: Egr=Vg, and Egc′=Egc=0. In short, all the surge voltage Vg is only applied to resistance component Rg.

In addition, when a predetermined time passes after a surge voltage Vg is applied, Egc is determined by an equation that includes time constant defined by resistance component Rg and capacity components Cg′ and Cg. When time further advances, equation (5) is transformed to the equation: Egc=Vg×Cg′/(Cg′+Cg), and voltage applied to the gate oxide film 3 is determined by partial pressure of Cg′ and Cg. Therefore, even if a surge voltage is applied for a given length of time, all the surge voltage is not applied to the gate oxide film 3.

A Manufacturing Process

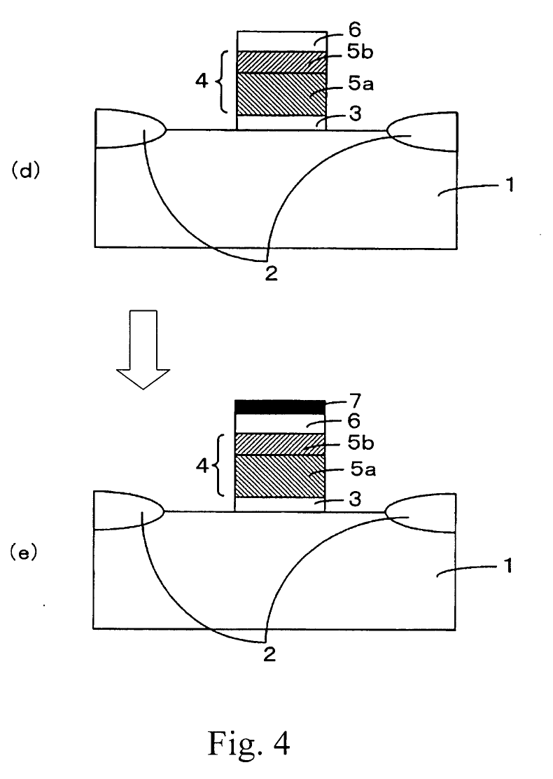

As is the case with the first embodiment of the present invention, a high resistance region, which is made of the low impurity ion concentration layer 5b, is formed on the place adjacent to or on the surface of the gate electrode 4 by the manufacturing process illustrated in FIG. 3. Next, as is shown in line (d) of FIG. 4, the silicon dioxide film 6 is formed on the above described high resistance region by thermal oxidation method or Chemical Vapor Deposition (CVD) method. Then, as is shown in line (e) of FIG. 4, the electrode 7, which is made of metal or silicide, is formed on the silicon oxide film 6. It is preferable to use metal, such as tungsten (W), for the electrode 7 to reduce resistance in the electrode 7. However, the melting point of metal is generally lower than that of silicon material, and accordingly silicide can be used to form the electrode 7 when there is a problem in the manufacturing process. Subsequently, an MOS transistor is formed by a heretofore known method (Not shown in the diagram).

An Example of a Protection Device

A protection device circuit in accordance with the second embodiment of the present invention can be formed by substituting the PMOS transistor Tr3 shown in FIG. 5, which illustrates an example of a protection device circuit in accordance with the first embodiment of the present invention, with an MOS transistor with a gate electrode structure in accordance with the second embodiment of the present invention. Actions of the protection device circuit in the second embodiment of the present invention are the same as or similar to those in the first embodiment of the present invention. Therefore, the explanation of the actions is omitted here.

Operation/Working-Effect

According to an MOS transistor type protection device in accordance with the second embodiment of the present invention, a series connection of a high resistance component by the low impurity ion concentration layer 5b and a capacity component by a silicon dioxide film 6 formed on the low impurity ion concentration layer 5b reduces surge voltage that is externally applied, and inhibits high surge voltage that is directly applied to the gate oxide film 3. Accordingly, even a gate oxide film whose thickness is as thin as that of an MOS transistor used for an internal circuit can provide adequate ESD protection performance, and reduce the incidence rate of destruction of the gate oxide film. In addition, the gate oxide film can function effectively against surge that continues for a certain period of time.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

This application claims priority to Japanese Patent Application No. 2004-175403. The entire disclosure of Japanese Patent Application No. 2004-175403 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

1. A method of manufacturing a semiconductor device comprising:
preparing a support substrate;
forming a device region and a device-separation region on said support substrate;
forming a gate insulating film in said device region;
forming a first gate electrode on said gate insulating film;
implanting first impurity ions into said first gate electrode; and
decreasing concentration of said first impurity ions by implanting second impurity ions with a polar character opposite from that of said first impurity ions into said first gate electrode.

2. The method of manufacturing a semiconductor device according to claim 1, wherein said first impurity ions are implanted into the whole of said first gate electrode.

3. The method of manufacturing a semiconductor device according to claim 2, wherein said second impurity ions are implanted into a place adjacent to a surface of said first gate electrode.

4. The method of manufacturing a semiconductor device according to claim 1, wherein said support substrate is an SOI substrate.

5. The method of manufacturing a semiconductor device according to claim 1, further comprising,
forming an insulating film on said first gate electrode, and
forming a second gate electrode on said insulating film after implantation of said second impurity ions into said first electrode.

6. The method of manufacturing a semiconductor device according to claim 5, wherein said gate insulating film is a silicon dioxide film.

7. The method of manufacturing a semiconductor device according to claim 6, wherein said second gate electrode is metal.

8. The method of manufacturing a semiconductor device according to claim 6, wherein said second gate electrode is a silicide.

9. A semiconductor device comprising:
a support substrate;
a gate insulating film being formed on said support substrate; and
a first gate electrode being formed on said gate insulating film and having a first part with a first impurity ion concentration and a second part adjacent to an upper side of said first part with a second impurity ion concentration lower than said first ion impurity concentration.

10. The semiconductor device according to claim 9, wherein said support substrate is an SOI substrate.

11. The semiconductor device according to claim 9, further comprising,
an insulating film being formed on said first gate electrode,
a second gate electrode being formed on said insulating film.

12. The semiconductor device according to claim 11, wherein said gate insulating film is a silicon dioxide film.

13. The semiconductor device according to claim 12, wherein said second gate electrode is metal.

14. The semiconductor device according to claim 12, wherein said second gate electrode is a silicide.

15. An electrostatic discharge protection circuit comprising:
an input/output terminal;
an internal circuit;
a line connecting said input/output terminal and said internal circuit; and
a protection circuit being connected to said line, said protection circuit having,
a silicon controlled rectifier being connected to said line by an anode, said silicon controlled rectifier having a PNP transistor and an NPN transistor,
a PMOS transistor being connected between said line and a base of said NPN transistor, said PMOS transistor having a gate electrode structure having,
a support substrate,
a gate insulating film being formed on said support substrate, and
a first gate electrode being formed on said gate insulating film and having a first part with a first impurity ion concentration and a second part adjacent to an upper side of said first part with a second impurity ion concentration lower than said first ion impurity concentration.

16. The electrostatic discharge protection circuit according to claim 15, wherein said support substrate is an SOI substrate.

17. The electrostatic discharge protection circuit according to claim 15, further comprising,
an insulating film being formed on said first gate electrode,
a second gate electrode being formed on said insulating film.

18. The electrostatic discharge protection circuit according to claim 17, wherein said gate insulating film is a silicon dioxide film.

19. The electrostatic discharge protection circuit according to claim 18, wherein said second gate electrode is metal.

20. The electrostatic discharge protection circuit according to claim 18, wherein said second gate electrode is a silicide.
